(19) United States
(12) Patent Application Publication
(10) Pub. No.: US 2024/0079259 A1
(43) Pub. Date: Mar. 7, 2024

(54) DUAL SIDED GLASS CARRIERS FOR MAKING PACKAGE SUBSTRATES

(71) Applicant: Intel Corporation, Santa Clara, CA (US)

(72) Inventors: Jacob VEHONSKY, Chandler, AZ (US); Onur OZKAN, Scottsdale, AZ (US); Vinith BEJUGAM, Chandler, AZ (US); Mao-Feng TSENG, Tempe, AZ (US); Andrea NICOLAS, Chandler, AZ (US); Nicholas HAEHN, Scottsdale, AZ (US)

(21) Appl. No.: 17/901,894

(22) Filed: Sep. 2, 2022

(51) Int. Cl. H01L 21/683; B32B 3/30; B32B 7/12; B32B 33/00; B32B 37/12; H01L 21/67

(52) U.S. Cl. CPC H01L 21/6835; B32B 3/30; B32B 7/12; B32B 33/00; B32B 37/12; H01L 21/67121; B32B 17/06; H01L 2221/68345

(57) ABSTRACT

The present disclosure is directed to a system that uses a dual surface substrate carrier that includes a first transparent support with a first top surface and first bottom surface, a second transparent support with a second top surface and second bottom surface, and a reflective film positioned between and attached to the first transparent support and the second transparent support. The first transparent support has a first set of trenches configured in the first top surface that form a first set of ridges between the plurality of trenches and the second transparent support has a second set of trenches configured in the second top surface that form a second set of ridges between the plurality of trenches. The first transparent support is also configured with a first build surface and the second transparent support is also configured with a second build surface that are platforms for building package substrates.

### BACKGROUND

In integrated circuit fabrication, the need to minimize costs and improve performance and yields are constant challenges. The integrated circuit (IC) substrate or IC package substrate is an increasingly important part of an IC package. In addition to being a support platform and protecting the bare IC or semiconductor die, they also facilitate connections between the IC and a printed circuit board's network of traces. They consist of several layers, which may or may not include a middle supporting core, which will typically contain a network of drill holes, vias, and conductor pads that may have a density that exceeds the density of conventional PCBs. A package substrate may have a significant influence on an IC's performance. Moreover, the use of 2.5D and 3D packaging technology has further increased the prominence of package substrates, which have also become increasingly complex to design and fabricate.

Depending on the size and consistency of the IC substrates, certain IC substrates may be fragile and easy to distort; in particular, in the case of coreless substrates. The manufacture of such package substrates is typically carried out on transparent substrate carriers, e.g., glass. Currently, a conventional substrate build-up process uses only one surface of the glass substrate carrier. For example, a bonding film may be applied to a top surface of the glass substrate carrier, and the package substrate formed on top of the bonding film, which is subsequently exposed to ultra-violet light through the backside of the substrate carrier to enable the detachment of the completed substrate. The ability to use the backside surface of the substrate carrier would allow for increased production of such package substrates.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIGS. 1A through 1D show an exemplary substrate system using a dual surface substrate carrier according to an aspect of the present disclosure;

FIGS. 2 and 2A show an exemplary cross-sectional view and top view, respectively, for a transparent support for a dual surface substrate carrier according to an aspect of the present disclosure;

FIGS. 3A and 3B show exemplary cross-sectional views of a dual surface substrate carrier having two transparent supports, and FIG. 3C shows a representative light pattern for the dual surface substrate carrier according to an aspect of the present disclosure;

FIGS. 4A and 4B show exemplary cross-sectional views of a dual surface substrate carrier having four transparent supports, and FIG. 4C shows a representative light pattern for the dual surface substrate carrier according to another aspect of the present disclosure; and

FIG. 5 shows a simplified flow diagram for a further exemplary method according to a further aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

The present disclosure is directed to a substrate manufacturing system that uses a dual surface substrate carrier. The dual surface substrate carrier includes a first transparent support providing a first build surface and a second transparent support providing a second build surface, with a reflective film positioned between the first and second transparent supports, and a light source that irradiates light off the reflective film towards the first and second build surfaces. The system also provides for one or more build-up tools or units for forming a first multilayer substrate and a second multilayer substrate on the first and second build surfaces, respectively, of the dual surface substrate carrier. The dual surface substrate carrier may have a form factor that will allow it to be used with existing package substrate fabrication tools.

In an aspect, the present disclosure is directed to a dual surface substrate carrier that includes a first transparent support with a first top surface and first bottom surface, a second transparent support with a second top surface and second bottom surface, and a reflective film positioned between and attached to the first transparent support and the second transparent support. The first transparent support has a first set of trenches configured in the first top surface that form a first set of ridges between the plurality of trenches and the second transparent support has a second set of trenches configured in the second top surface that form a second set of ridges between the plurality of trenches. In addition, the dual surface substrate may include a cover transport support that is attached to the first top surface of the first transparent transport and a third transparent support that is attached to the second bottom surface of the second transparent transport.

In another aspect, the present disclosure is direct to a method that provides a first transparent support with a first top surface and first bottom surface and etching a first set of trenches in the first top surface of the first transparent support to form a first set of ridges between the plurality of trenches. The method provides a second transparent support with a second top surface and a second bottom surface and etching a second set of trenches in the second top surface of the second transparent support to form a second set of ridges between the plurality of trenches. In addition, the method includes forming a reflective film on the first and/or second top surfaces, respectively, of the first and second transparent supports and providing an adhesive to attach the first transparent support to the second transparent support with the reflective film positioned therebetween to form a dual surface substrate carrier with a first build-up surface and a second build-up surface. The method further includes providing a first bonding film on the first build-up surface and a second bonding film on the second build-up surface and performing a build-up process to form a first multilayered substrate on the first bonding film on the first build-up surface and a second multilayered substrate on the second bonding film on the second build-up surface.

The technical advantages of the present disclosure may include, but are not limited to:
(i) providing two-sided or dual surface transparent substrate carriers that enable UV light exposure of bond films that attach two package substrates to the substrate carrier; and
(ii) doubling the production of package substrates from its current state and achieving greater economies of scale.

To more readily understand and put into practical effect the present substrate system using a dual surface substrate carrier, and the methods for building a package substrate, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

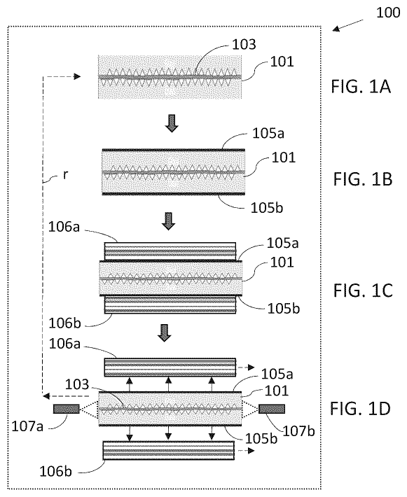

FIGS. 1A through 1D show an exemplary substrate system 100 using a dual surface substrate carrier 101 according to an aspect of the present disclosure. In FIG. 1A, the dual surface substrate carrier 101 with a thin reflective film or layer 103 is shown. The reflective film 103 may be made of a thin ultra-violet reflective metal layer, a thin reflective polymer layer, a polyethylene terephthalate layer, and/or an aluminum layer. In FIG. 1B, bonding films 105a and 105b may be placed on a top surface and a bottom surface of the dual surface substrate carrier by a conventional method (e.g., spray, spin coating, etc.) following a suitable cleaning of the top and bottom surfaces.

In an aspect of the present disclosure, the bonding films 105a and 105b may include a variety of different types of flexible film adhesives for the attachment of a package substrate to the dual surface substrate carrier 101 including dry epoxy film adhesives, tacky pressure sensitive epoxy film adhesives, thermally conductive insulating film and paste adhesives, and electrically conductive film and paste adhesives.

As shown in FIG. 1C, a package substrate 106a may be formed on the bonding film 105a and a package substrate 106b may be formed on the bonding film 105b. The present dual surface substrate carrier 101 enables the simultaneous fabrication of two package substrates. The package substrates 106a and 106b may be fabricated by conventional build-up methods and technologies and may be coreless substrates.

According to the present disclosure, the build-up for the package substrates may include conventional types of manufacturing methods, such as (i) subtraction methods that involve first applying a copper layer on a copper-clad laminate, followed by dry film coating to protect the circuits and thru-holes and etching off any unnecessary copper sheeting; (ii) addition methods that involve applying an insulating substrate, which contains a photosensitive catalyst, to an exposed circuit and selectively deposits a stream of a chemical copper compound on the areas forming the desired pattern; (iii) modified semi-additive process methods that involve electroplating a thin copper layer on a primary laminate layer, while applying a protective layer on the areas of the laminate layer where electroplating is not necessary, and removing excess copper through a flash etching process. It is understood that the build-up processes of the present substrate system may involve one or more semiconductor tools to perform the various steps and processes typically needed to fabricate a package substrate.

In an aspect shown in FIG. 1D, a pair of light sources 107a and 107b (e.g., ultra-violet (UV) light sources, infra-red (IR) light sources, etc.), may be positioned at the edges of the dual surface substrate carrier 101 to irradiate the bonding films 105a and 105b according to the present disclosure. It is within the scope of the present disclosure to use one or more light sources, so long as sufficient light irradiates the bonding films. For example, a single laser may be used to circumnavigate the perimeter of a dual surface substrate carrier. In this aspect, the UV light sources 107a and 107b may be configured to irradiate UV light, which is reflected by the reflective film or layer 103 towards the bonding films 105a and 105b. Thereafter, the package substrates 106a and 106b may be easily removed from the dual surface substrate carrier 101 and collected for use in fabricating semiconductor packages, at a collection unit that is part of the substrate system 100, while the dual surface substrate carrier 101 may be “recycled” (i.e., cleaned and prepared for reuse), as shown by the dashed lines “r”.

It is understood that exposing a bonding film to UV light and other artificial lights will affect its adhesive properties. The UV light or radiation can break down the chemical bonds in a polymer adhesive in a process called photodegradation. In an aspect, an exposed bonding film may lose its adhesive and other physical properties, which may result in cracking, buckling, chalking, and ultimately the loss of its bonding properties.

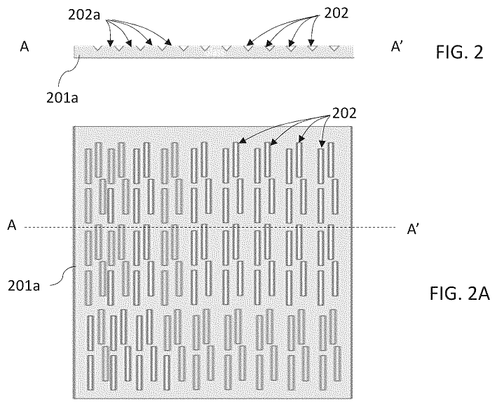

FIGS. 2 and 2A show an exemplary cross-sectional view and top view, respectively, for a transparent support 201a, which is a subunit of a dual surface substrate carrier, according to an aspect of the present disclosure. FIG. 2 is a cross-sectional view taken along the A-A′ section line shown in FIG. 2A.

In FIG. 2, the transparent support 201a may have a plurality of trenches 202, which may be formed by a conventional etching process. In an aspect, the transparent support 201a may be made of a transparent insulating material, such as glass or silicon. From the formation of the trenches 202, a plurality of ridges 202a may be formed therebetween. As shown in FIG. 2A, the plurality of trenches 202 may be placed in a pattern that provides for overlapping among the trenches to facilitate the reflection of the UV light used to irradiate the bonding films on a dual surface substrate carrier. In an aspect, the trench 202 may have predetermined dimensions, including lengths in the range of approximately 100 μm to 500 mm, widths in the range of approximately 5 μm to 1 mm, and depths in the range of approximately 5 μm to 1000 μm.

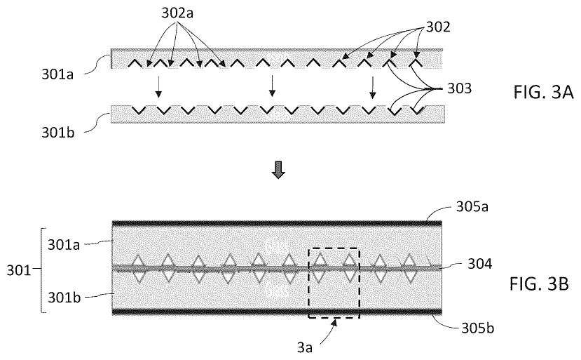

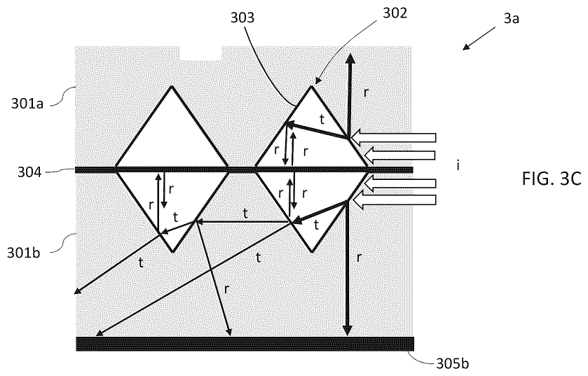

FIGS. 3A and 3B show exemplary cross-sectional views of a dual surface substrate carrier 301 having a first transparent support 301a and a second transparent support 301b according to an aspect of the present disclosure. In the aspect shown in FIG. 3A, the first and second transparent supports 301a and 301b may have a plurality of trenches 302 that have been pre-etched, and the formation of the trenches 302 results in a plurality of ridges 302a being formed.

In another aspect, reflective films 303 may be formed on the side surfaces of the plurality of trenches 302, as shown in FIG. 3A, after the etching of the trenches 302. The reflective film 303 may be made of a thin ultra-violet reflective metal layer, a thin reflective polymer layer, a polyethylene terephthalate layer, and/or an aluminum layer. In another aspect, the reflective films 303 may be made of a semi-reflective material, such as an opaque or tinted glass or polymer layer. The deposition of the reflective metal films 303 may be performed by selective or non-selective electroplating or other chemical deposition processes, with excess metal material removed by a masking and etching process and/or chemical mechanical polishing steps.

As shown in FIGS. 3A and 3B, the first transparent support 301a may be inverted and joined at its top surface to the top surface of the second transparent support 301b. In FIG. 3B, the first and second transparent supports 301a and 301b may be joined at their top surfaces by a fully reflective film 304, which may also act as an adhesive layer, to form the dual surface substrate carrier 301. The dual surface substrate carrier 301 will have a first build-up surface, which is shown covered by a first bonding film 305a, and a second build-up surface, which is shown covered by a second bonding film 305b, that may be used to fabricate package substrates.

In FIG. 3C, a representative light distribution pattern in a portion 3a of the dual surface substrate carrier 301 is shown. In this aspect, the reflective film 303 in the trenches 302 may be made of a semi-reflective material and the layer 304 positioned between the first and second transparent supports 301a and 301b may be made of a fully reflective material. In this aspect, an incident light “i” originates from one or more light sources (not shown) and is directed towards the plurality of trenches 302. In an aspect, the light “i” may be partially transmitted, as shown by directional arrows “t”, and partially reflected, as shown by the directional arrows “r”. The intensity of the reflected light “r” and the transmitted light “t” may decrease as they pass through the first and second transparent supports 301a and 301b. The reflected light “r” and the transmitted light “t” may ultimately be directed to the first and second bonding films 305a (not shown) and 305b to allow fabricated package substrates (not shown) to be separated and removed.

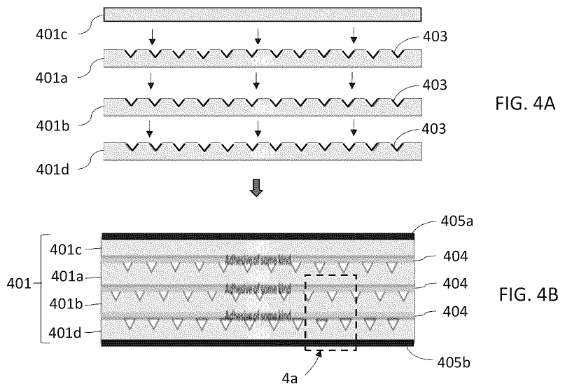

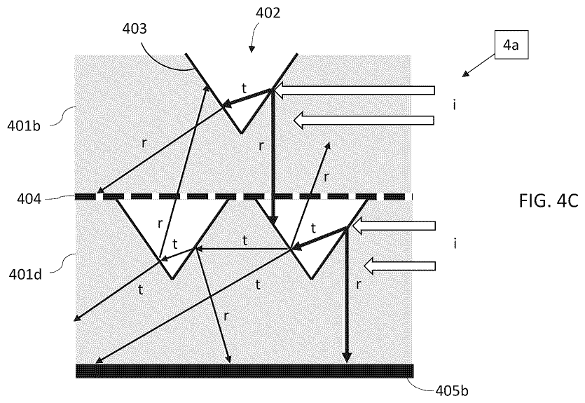

FIGS. 4A and 4B show exemplary cross-sectional views of a multilayered version of a dual surface substrate carrier 401 having four transparent supports according to another aspect of the present disclosure. As shown in FIG. 4A, a first transparent support 401a, a second transparent support 401b, and a third transparent support 401d may have pre-etched trenches and a reflective film 403 on their top surfaces. A cover transparent support 401c may be unetched as shown. In FIGS. 4A and 4B, the cover transparent support 401c, the first transparent support 401a, the second transparent support 401b, and the third transparent support 401d may be assembled in sequence, with bottom surfaces adjoined to top surfaces, and held together by adhesive layers 404 to form the multilayered dual surface substrate carrier 401. In addition, a first bonding film 405a may be formed on a top surface of cover transparent support 401c, and a second bonding film 406b may be formed on a bottom surface of the third transparent support 401d.

In another aspect, the multilayered dual surface substrate carrier 401 may provide tuneable control over the light distribution, as shown in FIG. 4C, using multiple transparent support layers to adjust the numbers, locations, and orientation of the trenches on one transparent support layer with respect to other transparent support layers. In another aspect, a multilayered version of the dual surface substrate carrier may have as many as 50 transparent support layers according to the present disclosure.

In FIG. 4C, a representative light distribution pattern for a portion 4a of the dual surface substrate carrier 401 is shown. In this aspect, the reflective films 403 on the side surfaces of the trenches 402 may be made of a semi-reflective material and the layers 404 may be of a transparent, non-reflective adhesive material that are positioned between the cover, first, second and third transparent supports 401c, 401a, 401b and 401d, respectively. In this aspect, an incident light “i” originates from one or more light sources (not shown) and is directed towards the plurality of trenches 402. In an aspect, the light “i” may be partially transmitted, as shown by directional arrows “t”, and partially reflected, as shown by the directional arrows “r”. The intensity of the reflected light “r” and the transmitted light “t” may decrease as they pass through the covering, first, second and third transparent supports 401c, 401a, 401b and 401d. The reflected light “r” and the transmitted light “t” may be ultimately directed to the first and second bonding films 405a (not shown) and 405b to allow fabricated package substrates (not shown) to be separated and removed.

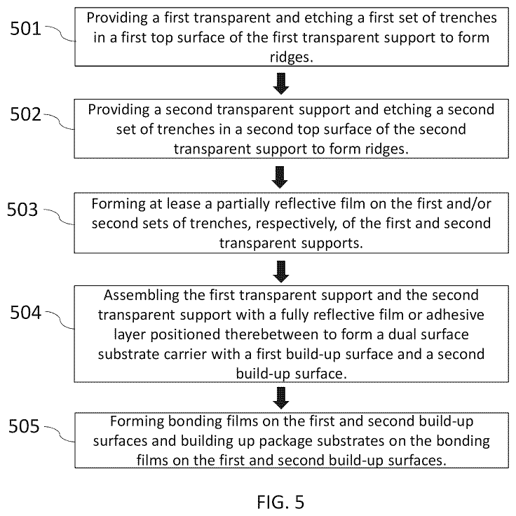

FIG. 5 shows a simplified flow diagram for a further exemplary method according to a further aspect of the present disclosure. In an aspect, the present method may be able to provide semiconductor device or other product authentication using the operations below.

The operation 501 may be directed to providing a first transparent and etching a first set of trenches in a first top surface of the first transparent support to form ridges.

The operation 502 may be directed to providing a second transparent support and etching a second set of trenches in a second top surface of the second transparent support to form ridges.

The operation 503 may be directed to forming at least a partially reflective film on the first and/or second sets of trenches, respectively, of the first and second transparent supports.

The operation 504 may be directed to assembling the first transparent support and the second transparent support with a fully reflective film or adhesive layer positioned therebetween to form a dual surface substrate carrier with a first build-up surface and a second build-up surface.

The operation 505 may be directed to forming bonding films on the first and second build-up surfaces and building up package substrates on the bonding films on the first and second build-up surfaces.

It will be understood that any specific property described herein for a particular aspect of a substrate system with a dual surface substrate carrier and method may also generally hold for any of the other aspects thereof described herein. It will also be understood that any specific property described herein for a specific method may generally hold for any of the other methods described herein. Furthermore, it will be understood that for any system, component or method described herein, not necessarily all the components or operations described will be enclosed in the system, component, or method, but only some (but not all) components or operations may be enclosed.

To more readily understand and put into practical effect the present reticle assemblies and sensor assemblies, they will now be described by way of examples. For the sake of brevity, duplicate descriptions of features and properties may be omitted.

### EXAMPLES

Example 1 provides a substrate system including a dual surface substrate carrier including a first transparent support providing a first build surface, a second transparent support providing a second build surface, at least a partially reflective film positioned on portions of the first and second transparent supports, and a light source, for which the light source irradiates light off the at least partially reflective film towards the first and second build surfaces.

Example 2 may include the substrate system of example 1 and/or any other example disclosed herein, for which the dual surface substrate carrier further includes a first bonding film positioned on the first build surface and a second bonding film positioned on the second build surface and, for which the light source irradiates the first and second bonding films.

Example 3 may include the substrate system of example 2 and/or any other example disclosed herein, further includes one or more build-up units for forming a first multilayer substrate on the first bonding film and a second multilayer substrate on the second bonding film.

Example 4 may include the substrate system of example 3 and/or any other example disclosed herein, further includes a collection unit for removing and collecting the first and second multilayer substrates from the dual surface substrate carrier and collecting the dual surface substrate carrier for reuse.

Example 5 may include the substrate system of example 1 and/or any other example disclosed herein, further comprising a fully reflective film positioned between the first and second transparent supports, the fully reflective film is configured from aluminum.

Example 6 may include the substrate system of example 1 and/or any other example disclosed herein, for which the light source further includes one or more ultra-violet light or light emitting diodes configured to irradiate edges of the dual surface substrate carrier.

Example 7 provides a dual surface substrate carrier including a first transparent support with a first top surface and first bottom surface, a second transparent support with a second top surface and second bottom surface, and an adhesive film positioned between and attached to the first transparent support and the second transparent support.

Example 8 may include the dual surface substrate carrier of example 7 and/or any other example disclosed herein, for which the first transparent support includes a first set of trenches configured in the first top surface that form a first set of ridges between the plurality of trenches and the first set of trenches having side surfaces with at least a partially reflective film.

Example 9 may include the dual surface substrate carrier of example 8 and/or any other example disclosed herein, for which the second transparent support includes a second set of trenches configured in the second top surface that form a second set of ridges between the plurality of trenches and the second set of trenches having side surfaces with at least a partially reflective film.

Example 10 may include the dual surface substrate carrier of example 7 and/or any other example disclosed herein, for which the first and second transparent supports are stacked with the first top surface opposing the second top surface and the adhesive film is made of a fully reflective material that is positioned between and attached to the first top surface of the first transparent support and the second top surface of the second transparent support.

Example 11 may include the dual surface substrate carrier of example 7 and/or any other example disclosed herein, for which the first bottom surface of the first transparent support is configured as a first build surface and the second bottom surface of the second transparent support is configured as a second build surface, for which the first and second build surfaces provide platforms for building package substrates.

Example 12 may include the dual surface substrate carrier of example 9 and/or any other example disclosed herein, further includes a cover transparent support with a cover top surface and a cover bottom surface, and a third transparent support with a third top surface and a third bottom surface, the third transparent support comprising a third set of trenches configured in the third top surface that form a third set of ridges between the plurality of trenches, for which the cover, first, second and third transparent supports are stacked in sequence with their bottom surface attached to the top surface below to form a multilayered dual surface substrate carrier.

Example 13 may include the dual surface substrate carrier of example 12 and/or any other example disclosed herein, for which the cover top surface of the cover transparent support is configured as a first build surface and the third bottom surface of the third transparent support is configured as a second build surface of the multilayered dual surface substrate carrier.

Example 14 may include the dual surface substrate carrier of example 7 and/or any other example disclosed herein, for which the fully reflective material includes a thin ultra-violet reflective metal layer, a thin reflective polymer layer, a polyethylene terephthalate layer, and/or an aluminum layer.

Example 15 provides a method that includes providing a first transparent support with a first top surface and first bottom surface, etching a first set of trenches in the first top surface of the first transparent support, for which the first set of trenches form a first set of ridges between the plurality of trenches, providing a second transparent support with a second top surface and a second bottom surface, etching a second set of trenches in the second top surface of the second transparent support, for which the second set of trenches form a second set of ridges between the plurality of trenches, forming at least partially reflective films on side surfaces of the first and second sets of trenches, respectively, of the first and second transparent supports, and providing an adhesive to attach the first transparent support to the second transparent support to form a dual surface substrate carrier with a first build-up surface and a second build-up surface.

Example 16 may include the method of example 15 and/or any other example disclosed herein, further includes providing a cover transparent support with a cover top surface and a cover bottom surface, providing a third transparent support with a third top surface and third bottom, etching a third set of trenches in the third top surface of the third transparent support, for which the third set of trenches form a third set of ridges between the plurality of trenches, and forming a third reflective film on the side surfaces of the third set of trenches of the third transparent support.

Example 17 may include the method of example 16 and/or any other example disclosed herein, further includes assembling the cover transparent support and the third transparent support with the first and second transparent supports to form the dual surface substrate carrier with a first build-up surface and a second build-up surface.

Example 18 may include the method of example 15 and/or any other example disclosed herein, further includes providing a first bonding film on the first build-up surface and a second bonding film on the second build-up surface.

Example 19 may include the method of example 18 and/or any other example disclosed herein, further includes performing a build-up process to form a first multilayered substrate on the first bonding film on the first build-up surface and a second multilayered substrate on the second bonding film on the second build-up surface.

Example 20 may include the method of example 19 and/or any other example disclosed herein, further includes using an ultra-violet (UV) light source to direct an UVlight to the edges of the dual surface substrate carrier to irradiate the first and second bonding films, removing the first and second multilayered substrates from the dual surface substrate carrier, and reusing the dual surface substrate carrier.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A substrate system comprising:
a dual surface substrate carrier comprising:
a first transparent support providing a first build surface;
a second transparent support providing a second build surface; and
at lease a partially reflective film positioned on portions of the first and second transparent supports;
a light source, wherein the light source irradiates light off the at least partially reflective film towards the first and second build surfaces.

2. The substrate system of claim 1, wherein the dual surface substrate carrier further comprises a first bonding film positioned on the first build surface and a second bonding film positioned on the second build surface, and wherein the light source irradiates the first and second bonding films.

3. The substrate system of claim 2, further comprises one or more build-up units for forming a first multilayer substrate on the first bonding film and a second multilayer substrate on the second bonding film.

4. The substrate system of claim 3, further comprises a collection unit for removing and collecting the first and second multilayer substrates from the dual surface substrate carrier and collecting the dual surface substrate carrier for reuse.

5. The substrate system of claim 1, further comprising a fully reflective film positioned between the first and second transparent supports, the fully reflective film is configured from aluminum.

6. The substrate system of claim 1, wherein the light source further comprises one or more ultra-violet light or light emitting diodes configured to irradiate edges of the dual surface substrate carrier.

7. A dual surface substrate carrier comprising:
a first transparent support with a first top surface and a first bottom surface;
a second transparent support with a second top surface and a second bottom surface; and
an adhesive film positioned between and attached to the first transparent support and the second transparent support.

8. The dual surface substrate carrier of claim 7, wherein the first transparent support comprises a first set of trenches configured in the first top surface that form a first set of ridges between the plurality of trenches and the first set of trenches having side surfaces with at least a partially reflective film.

9. The dual surface substrate carrier of claim 8, wherein the second transparent support comprises a second set of trenches configured in the second top surface that form a second set of ridges between the plurality of trenches and the second set of trenches having side surfaces with at least a partially reflective film.

10. The dual surface substrate carrier of claim 7, wherein the first and second transparent supports are stacked with the first top surface opposing the second top surface and the adhesive film is made of a fully reflective material that is positioned between and attached to the first top surface of the first transparent support and the second top surface of the second transparent support.

11. The dual surface substrate carrier of claim 10, wherein the first bottom surface of the first transparent support is configured as a first build surface and the second bottom surface of the second transparent support is configured as a second build surface, wherein the first and second build surfaces provide platforms for building package substrates.

12. The dual surface substrate carrier of claim 9, further comprises:
a cover transparent support with a cover top surface and a cover bottom surface; and
a third transparent support with a third top surface and a third bottom surface, the third transparent support comprising a third set of trenches configured in the third top surface that form a third set of ridges between the plurality of trenches and the third set of trenches having side surfaces with at least a partially reflective film,
wherein the cover, first, second, and third transparent supports are stacked in sequence with their bottom surface attached to the top surface below to form a multilayered dual surface substrate carrier.

13. The dual surface substrate carrier of claim 12, wherein the cover top surface of the cover transparent support is configured as a first build surface and the third bottom surface of the third transparent support is configured as a second build surface of the multilayered dual surface substrate carrier.

14. The dual surface substrate carrier of claim 10, wherein the fully reflective material comprises a thin ultra-violet reflective metal layer, a thin reflective polymer layer, a polyethylene terephthalate layer, and/or an aluminum layer.

15. A method comprising:
providing a first transparent support with a first top surface and a first bottom surface;
etching a first set of trenches in the first top surface of the first transparent support, wherein the first set of trenches form a first set of ridges between the plurality of trenches;
providing a second transparent support with a second top surface and a second bottom surface;
etching a second set of trenches in the second top surface of the second transparent support, wherein the second set of trenches form a second set of ridges between the plurality of trenches;
forming at least partially reflective films on side surfaces of the first and second sets of trenches, respectively, of the first and second transparent supports; and
providing an adhesive layer to attach the first transparent support to the second transparent support to form a dual surface substrate carrier with a first build-up surface and a second build-up surface.

16. The method of claim 15, further comprises:
providing a cover transparent support with a cover top surface and a cover bottom surface;
providing a third transparent support with a third top surface and third bottom;
etching a third set of trenches in the third top surface of the third transparent support, wherein the third set of trenches form a third set of ridges between the plurality of trenches; and
forming a third reflective film on the side surfaces of the third set of trenches of the third transparent support.

17. The method of claim 16, further comprises:
assembling the cover transparent support and the third transparent support with the first and second transparent supports to form the dual surface substrate carrier with a first build-up surface and a second build-up surface.

18. The method of claim 15, further comprises providing a first bonding film on the first build-up surface and a second bonding film on the second build-up surface.

19. The method of claim 18, further comprises performing a build-up process to form a first multilayered substrate on the first bonding film on the first build-up surface and a second multilayered substrate on the second bonding film on the second build-up surface.

20. The method of claim 19, further comprises:
using an ultra-violet (UV) light source to direct an UV-light to edges of the dual surface substrate carrier to irradiate the first and second bonding films;
removing the first and second multilayered substrates from the dual surface substrate carrier; and
reusing the dual surface substrate carrier.
